(19) United States
(12) Patent Application Publication
(10) Pub. No.: US 2025/0271303 A1
(43) Pub. Date: Aug. 28, 2025

(54) INTELLIGENT SENSING ENABLED BY TUNABLE MOIRÉ GEOMETRY AND TUNABLE QUANTUM GEOMETRY

(71) Applicants: BOARD OF REGENTS, THE UNIVERSITY OF TEXAS SYSTEM, Austin, TX (US); Yale University, New Haven, CT (US)

(72) Inventors: Fan Zhang, Plano, TX (US); Patrick Ka Man Cheung, Hong Kong (CN); Fengnian Xia, New Haven, CT (US); Chao Ma, New Haven, CT (US); Shaofan Yuan, New Haven, CT (US)

(21) Appl. No.: 18/855,468

(22) PCT Filed: Apr. 11, 2023
(86) PCT No.: PCT/US2023/065635

§ 371 Date: Oct. 9, 2024

Related U.S. Application Data
(60) Provisional application No. 63/362,783, filed on Apr. 11, 2022.

(51) Int. Cl. G01J 3/28; G01J 1/42; G01J 4/00

(52) U.S. Cl. CPC G01J 3/28; G01J 1/42; G01J 4/00

(57) ABSTRACT

A photodetector is provided comprising: a twisted Moiré superlattice: a first dielectric layer disposed on a first side of the Moiré superlattice: a second dielectric layer disposed on a second side of the Moiré superlattice: two contact electrodes connected to the Moiré superlattice, wherein the contact electrodes collect photovoltages or photocurrents in response to incident light that excites the Moiré superlattice; and one or more tuning gates that tune the photovoltages or photocurrents collected by the contact electrodes and produce photovoltage maps or photocurrent maps based on the photovoltages or photocurrents. A neural network in communication with the photodetector is trained to concurrently determine intensity, polarization, and wavelength of the incident light according to a photovoltage map or photocurrent map generated in response to the incident light by the tuning gates.

### CROSS-REFERENCE TO RELATED APPLICATION

This application claims the benefit of U.S. Provisional Application Ser. No. 63/362,783, filed Apr. 11, 2022, entitled “Intelligent Sensing Enabled by Tunable Moiré Geometry and Tunable Quantum Geometry”, which is incorporated herein by reference in its entirety.

### STATEMENT OF GOVERNMENT INTEREST

This invention was made with government support under Grant Nos. DMR1945351 and EFMA1741693 awarded by the National Science Foundation and Grant No. W911NF-18-1-0416 awarded by the Army Research Office. The government has certain rights in the invention.

### BACKGROUND INFORMATION

### 1. Field

The present disclosure relates generally to photodetection and measurement, and more specifically to photodetection using a Moiré superlattice and neural network.

### 2. Background

Quantum geometric properties of Bloch wave functions in solids, i.e., Berry curvature and quantum metric, are known to significantly influence the ground- and excited-state behavior of electrons. Bulk photovoltaic effect (BPVE), a nonlinear phenomenon depending on the polarization of excitation light, is largely governed by the quantum geometric properties in optical transitions. Infrared BPVE has yet to be observed in graphene or moiré systems, although exciting strongly correlated phenomena related to quantum geometry have been reported in this emergent platform.

Therefore, it would be desirable to have an apparatus and system that take into account at least some of the issues discussed above, as well as other possible issues.

### SUMMARY

An illustrative embodiment provides a photodetector comprising: a twisted Moiré superlattice; a first dielectric layer disposed on a first side of the Moiré superlattice; a second dielectric layer disposed on a second side of the Moiré superlattice; two contact electrodes connected to the Moiré superlattice, wherein the contact electrodes collect photovoltages or photocurrents in response to incident light that excites the Moiré superlattice; and one or more tuning controls that tune the photovoltages or photocurrents collected by the contact electrodes and produce photovoltage maps or photocurrent maps based on the photovoltages or photocurrents. A neural network in communication with the photodetector is trained to concurrently determine intensity, polarization, and wavelength of the incident light according to a photovoltage map or photocurrent map generated in response to the incident light by the tuning controls.

Another illustrative embodiment provides a method for training a neural network to measure quantities of light. The method comprises: inputting a set of known data points regarding light intensity, polarization, and wavelength and corresponding photovoltage maps or photocurrent maps into a neural network as a training dataset; shining a set of incident light of the known intensity, polarization, and wavelength on a photodetector comprising a twisted Moiré superlattice, wherein the photodetector is in communication with the neural network; generating a set of photovoltage maps or photocurrent maps as functions of voltages generated by one or more tuning controls in the photodetector that tune photovoltages or photocurrents collected by contact electrodes connected to the Moiré superlattice in response to excitement of the Moiré superlattice by the incident light; inputting the photovoltage maps or photocurrent maps into the neural network; concurrently predicting, by the neural network, the intensity, polarization, and wavelength of the incident light from each of the photovoltage maps or photocurrent maps; comparing the predicted intensity, polarization, and wavelength to the known intensity, polarization, and wavelength in the set of known data points; in response to predicted intensity, polarization, and wavelength that do not match the known intensity, polarization, and wavelength, adjusting parameters of the neural network; and retraining the neural network until errors of all training data reach are minimized.

Another illustrative embodiment provides a method for measuring qualities of light. The method comprises shining an incident light of unknown intensity, polarization, and wavelength on a photodetector, the photodetector comprising: a twisted Moiré superlattice; a first dielectric layer disposed on a first side of the Moiré superlattice; a second dielectric layer disposed on a second side of the Moiré superlattice; two contact electrodes connected to the Moiré superlattice, wherein the contact electrodes collect photovoltages or photocurrents in response to excitement of the Moiré superlattice by the incident light; and one or more tuning controls that tune the photovoltages or photocurrents collected by the contact electrodes. A photovoltage map or photocurrent map is generated as a function of voltages generated by the tuning controls in response to excitement of the Moiré superlattice by the incident light and then input into a neural network in communication with the photodetector. The neural network concurrently determines the intensity, polarization, and wavelength of the incident light according to the photovoltage map or photocurrent map.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 shows a schematic of a hexagonal boron nitride (hBN) encapsulated TDBG photodetector fabricated using a previously reported deterministic transfer technique in accordance with an illustrative embodiment;

FIG. 2 shows a schematic of twisted double bilayer graphene (TDBG) with varying atomic registries including ABBC, ABCA, and ABAB in accordance with an illustrative embodiment;

FIG. 3 shows the principles of neural network polarimetry and wavelength detection in accordance with an illustrative embodiment;

FIG. 4 depicts a side cross-section view of a sequence for manufacturing a photodetector in accordance with an illustrative embodiment in accordance with an illustrative embodiment;

FIG. 5 depicts a perspective view of a sequence for manufacturing a photodetector in accordance with an illustrative embodiment;

FIG. 6 depicts a flowchart for training a neural network to measure quantities of light in accordance with an illustrative embodiment;

FIG. 7A depicts a schematic of the middle two layers of the lattice structure of TDBG, forming twisted bilayer graphene (TBG), and its C_{6z} and C₂ₓ axes; and

FIG. 7B depicts a schematic of the top or bottom Bernal bilayer graphene and how it changes under the C_{2z} rotation.

### DETAILED DESCRIPTION

The illustrative embodiments recognize and take into account one or more different considerations. The illustrative embodiments recognize and take into account that quantum geometric properties of Bloch wave functions, known as Berry curvature and quantum metric, are crucial in determining the ground-state behavior of electrons, such as the electric polarization of crystals, orbital magnetization, quantum, and anomalous Hall effects. They also play critical roles in the recently discovered superconductivity and ferromagnetism in graphene moiré superlattices. In fact, bulk photovoltaic effect (BPVE), a nonlinear direct-current photoresponse dependent on light polarization, is also governed by physical quantities associated with Berry curvature and quantum metric. In this work, we report the tunable infrared BPVE in twisted double bilayer graphene (TDBG). Utilizing its tunability, we have generated photovoltage (Vₚₕ) mappings that are unique for different polarization states and infrared wavelengths. Furthermore, by leveraging a trained convolutional neural network (CNN), we have demonstrated an intelligent TDBG photodetector with a footprint of 3×3 μm² capable of extracting the full Stokes parameters and the wavelength of an incident light simultaneously from the Vₚₕ mapping. This device has unique operational mechanisms compared with previous demonstrations. For example, prior miniaturized polarimeters usually utilize meta-surfaces, anisotropic or chiral materials, in which light is selectively scattered or absorbed depending on its polarization state. However, anisotropic and chiral materials typically cannot provide full-Stokes detection; meta-surfaces require extra photodetectors and usually have a narrow operational wavelength range due to their resonant nature.

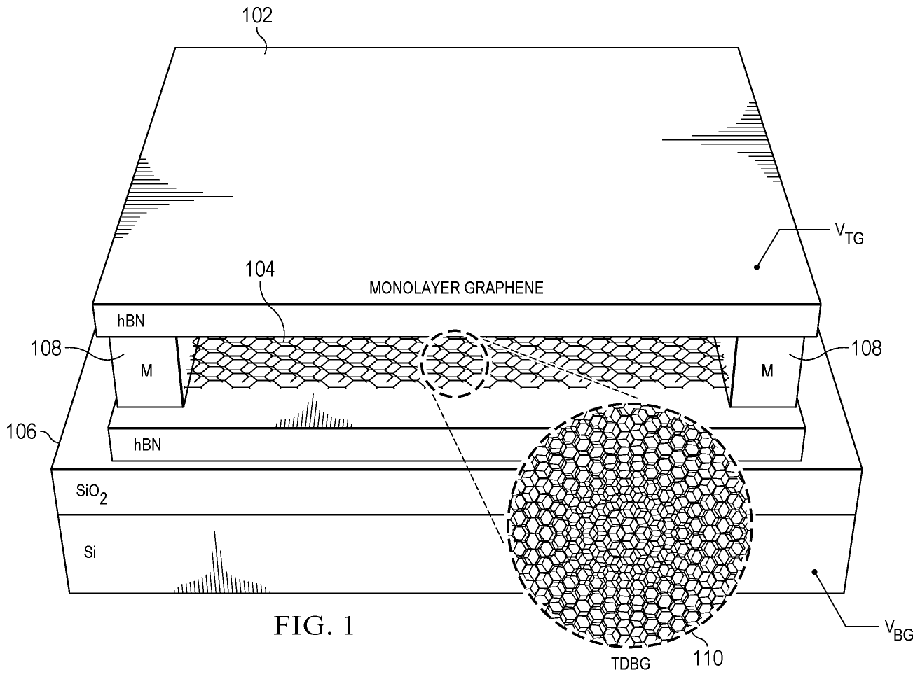

FIG. 1 shows a schematic of a hexagonal boron nitride (hBN) encapsulated TDBG photodetector fabricated using a previously reported deterministic transfer technique in accordance with an illustrative embodiment. Independent control of the carrier concentration n and the vertical displacement field D in our TDBG device is realized by tuning both the top-gate (V_{TG}) and back-gate (V_{BG}) voltages. Here we use the moiré band structures of a 1.2° TDBG at different interlayer potential differences ΔV=0, 50 and 100 meV to illustrate the band structure evolvement under D. The superlattice-induced insulating states at full fillings of the lowest-energy moiré bands, i.e., 4 electrons or holes per moiré unit cell, (denoted by the light green bars) are suppressed with increasing D and closed at large D. By contrast, a band gap opens at the charge neutrality point (CNP) and increases with D. Such evolution features have been reported in previous works and are generic for TDBG with a twist angle from ˜1.1° to 2°. Prominent resistance peaks are observed along the CNP at substantial D, consistent with our calculated band structure evolution and other transport studies. To determine the twist angle of TDBG, we performed temperature dependent R measurements. Regions with positive temperature coefficient of resistance (TCR) are expected to arise from insulating states in which thermal excitation of carriers reduces the resistance. TCR maxima occur at finite D along the CNP (gray dashed lines), corresponding to field-induced band gaps. Additionally, local maxima of TCR also appear at n=3.2×10¹² cm⁻², implying the presence of the superlattice gap at the electron side. The formation of TDBG moiré superlattice is further confirmed by the temperature-dependent R measurements. We assign this carrier concentration to be the 4-electron full filling and estimate the twist angle to be 1.2°, close to the angle targeted in stacking.

A graphene monolayer 102 is on top of the hBN encapsulated TDBG 104, functioning as the top-gate electrode. A degenerately doped silicon substrate 106 is used as the back-gate electrode. Metal contacts 108 are made along the two edges of the stack. The inset 110 more clearly depicts the TDBG moiré superlattice 104.

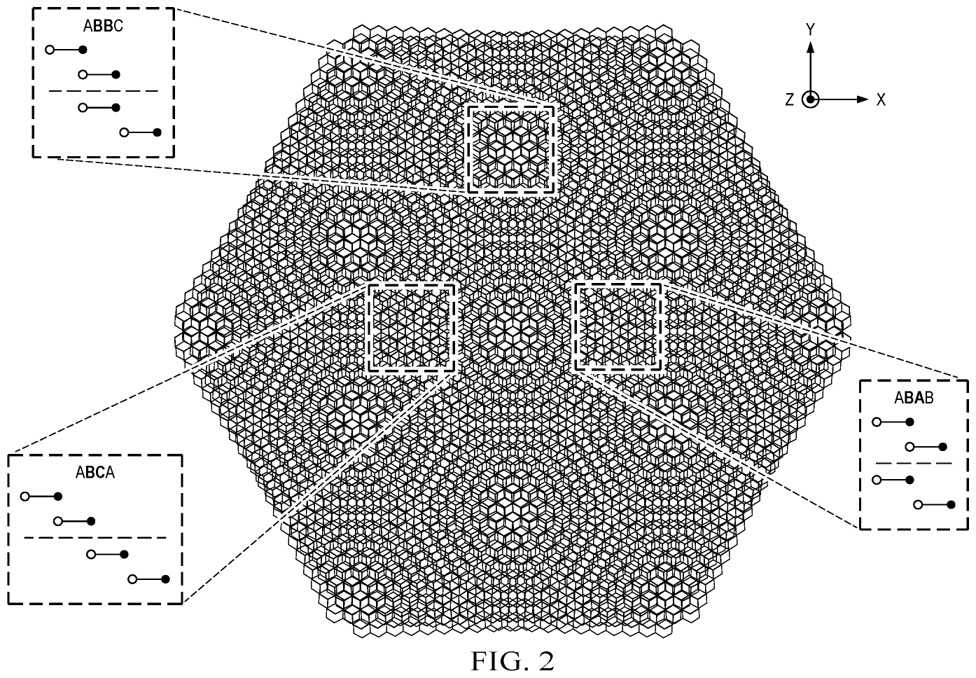

The BPVE is a nonlinear optic phenomenon, consisting of shift (linear BPVE) and injection (circular BPVE) currents generated under linearly and circularly polarized excitations, respectively² (Methods). We first focus on the linear BPVE, which is related to the electric field E of incident light through a third-rank nonlinear conductivity tensor σ by⁵ Vᵢ∝Jᵢ=Σ_{j,k}σᵢⱼₖEⱼEₖ in the leading order. Here, Vᵢ, Jᵢ, σᵢⱼₖ, and E_{j,k} are elements of photovoltage, photocurrent density, nonlinear conductivity, and optical field with i,j,k={x,y,z} (Methods). The crystalline symmetry of a material sets strong constraints on its σ (Methods). FIG. 2a shows a schematic of TDBG with varying atomic registries including ABBC, ABCA, and ABAB. TDBG has three-fold rotation (C_{3z}) and two-fold rotation (C₂ₓ) symmetries, and the latter is broken in our devices by D (see detailed symmetry analysis in Supplementary Information). Following our symmetry analysis (Methods), we deduce two nontrivial, independent elements, σₓₓₓ and σ_{yyy}, in the conductivity tensor, which give rise to the unique polarization dependence of nonlinear photovoltage Vₚₕ under normal incidence of linearly polarized light (Methods):

$${V}_{ph} ∝ {E}^{2} ( {σ}_{xxx} cos ( 2 ψ ) - {σ}_{yyy} sin ( 2 ψ ) ) ,$$

where ψ is the orientation angle of the in-plane field E with respect to the voltage collection direction (x-axis). The amplitude of Vₚₕ oscillation is proportional to (σₓₓₓ²+σ_{yyy}²)^{1/2}, with a phase ψ₀ determined as ψ₀=arctan(σ_{yyy}/σₓₓₓ). Furthermore, from the expression of σₓₓₓ and σ_{yyy} (Method) it is evident that the quantum geometric properties, i.e., the inter-band Berry connections, play an essential role in determining σ and hence the BPVE. By integrating Sₓₓₓ and S_{yyy} over the mBZ, we obtain the dependence of σₓₓₓ and σ_{yyy} on ℏω at different E_{F} and ΔV. Remarkably, both E_{F} and ΔV can effectively tune the magnitude and the polarity of σₓₓₓ and σ_{yyy} and hence the resulting linear BPVE. Additionally, σₓₓₓ and σ_{yyy} are strong and oscillating in a broad spectral range. Unlike any pristine material, the large inter-layer moiré potential in TDBG lead to abundant states with substantial quantum geometric properties from multiple minibands available for the optical transitions over a wide energy range. Therefore, TDBG is the simplest system for achieving tunable BPVE enabled by moiré quantum geometry.

In experiments, we measure Vₚₕ in our TDBG device under normal light incidence at 7.7 and 5 μm at different V_{TG} and V_{BG}, without applying an external in-plane bias (Methods). Half-wave plates at corresponding wavelengths are used to rotate the polarization of the incident linearly polarized light, and the device is held at T=79 K for all measurements except for temperature-dependent ones. We first fix ψ and measure Vₚₕ as a function of V_{TG} and V_{BG} at 7.7 μm. In Vₚₕ mappings, tuning V_{TG} and V_{BG} changes both the magnitude and polarity of Vₚₕ. Maximum and minimum Vₚₕ occur around CNP at large D, and the polarity flips by reversing the direction of D. Away from the extrema, Vₚₕ shows complex dependences on V_{TG} and V_{BG} for both ψ=45° and 135°. To better reveal the polarization dependence of Vₚₕ, we measure Vₚₕ as a function of v at multiple sets of (V_{BG}, V_{TG}). Each set of measured Vₚₕ can be well fitted by Vₚₕ=V_{c} cos(2ψ)+Vₛ sin(2ψ)+V_{const}. Here, V_{const} represents the offset voltage. The magnitudes and polarities of both fitting parameters V_{c} and Vₛ are largely tunable by gate voltages, leading to Vₚₕ's tunable amplitude and phase, (V_{c}²+Vₛ²)^{1/2} and ψ′₀=arctan(V_{c}/Vₛ), respectively. The maximum extrinsic responsivity reaches 3.7 V/W at 7.7 μm, defined as the peak amplitude divided by the power on device. The converted short-circuit photocurrent response is 0.74 mA/W. This photoresponse is surprisingly strong in the infrared range^{8,9} considering its second-order nature. Our experimental observation is consistent with our theoretical analysis that two independent nonlinear conductivity elements σₓₓₓ and σ_{yyy} are tunable by E_{F} and D, giving rise to the unique polarization dependence of Vₚₕ. A similar tuning effect on Vₚₕ by V_{BG} and V_{TG} is observed, and the magnitudes and polarities of V_{c} and Vₛ are different from those under the excitation of 7 μm light. In addition, a similar strong, electrically tunable linear BPVE has been observed in another TDBG device. We expect that the linear BPVE is prominent in TDBG with a wide range of twist angles, as shown by our theoretical calculations.

Furthermore, we investigate the nonlinear photoresponse when the light is modulated between linear and circular polarizations by first passing it through a half-wave plate (fast axis fixed) and then a quarter-wave plate before focusing it onto the TDBG device. A two-periodicity waveform can be used for fitting the dependence of Vₚₕ on θ, Vₚₕ=V_{circular}+Vₗᵢₙₑₐᵣ+V_{const}=V₁ cos(2θ+θ₀)+V₂ sin(4θ+θ′₀)+V_{const}. The component Vₗᵢₙₑₐᵣ with a 90-degree periodicity in θ stems from the linear BPVE discussed above (the light resumes linear polarization every 90 degree when rotating a quarter-wave plate), while the other component V_{circular} arises from the circular BPVE that is closely related to the inter-band Berry curvature dipoles. Similar to the linear BPVE, the amplitude of V_{circular} can be tuned while the phase of V_{circular} can be switched by 180 degrees by the gate voltages, which implies the electrical tunability of the inter-band Berry curvature dipoles in TDBG. In principle, the C_{3z} symmetry of TDBG results in zero in-plane circular BPVE, because the sum of the inter-band Berry curvature dipoles over the mBZ vanishes. However, possible strain or interaction-induced nematic phase may weakly break the C_{3z} symmetry, generating the observed circular BPVE. The simultaneous observations of both linear and circular BPVE in TDBG and their tunability by gate voltages are unprecedented (Methods), leading to distinct patterns in the Vₚₕ mappings that are both polarization- and wavelength-dependent.

FIG. 2 depicts a schematic of the moiré pattern and atomic registries of TDBG. The white and black spheres represent the two sublattice (A and B) in each graphene monolayer. The hexagonal moiré pattern is similar to that of TBG but with the AA, AB, and BA atomic registries replaced by ABBC, ABCA, and ABAB, respectively. TDBG has three-fold rotation (C_{3z}) and two-fold rotation (C₂ₓ) symmetries, and the latter is broken in the devices by D. Calculated integrands Sₓₓₓ and S_{yyy} are used in the evaluation of the nonlinear conductivity elements σₓₓₓ and σ_{yyy} in the mBZ (σ_{xxx (yyy)}=∫d²kS_{xxx(yyy)}).

Photovoltage (Vₚₕ) is a function of the angle of quarter-wave plate (QWP) at different gate voltage biases (V_{BG}, V_{TG}). The incident light first passes through a half-wave plate (direction of fast axis fixed) and then a quarter-wave plate (direction of fast axis changing upon rotation). The offset of the linear polarization state from e=0 is caused by the half-wave plate, of which the fast axis is ˜60° away from the z axis in laboratory coordinate. Two components, Vₗᵢₙₑₐᵣ and V_{circular}, with the periodicity of 90 and 180 degrees can be identified by fitting. Vₗᵢₙₑₐᵣ and V_{circular} can be constructed from fittings, from which a doubled periodicity of V_{circular} compared to Vₗᵢₙₑₐᵣ is observed. The amplitudes and phases of both components are tunable by gate voltage biases (V_{BG}, V_{TG}).

Next, we discuss how the tunable BPVE can be leveraged for sensing of polarization, power and wavelength. For a different polarization, the dependence of Vₚₕ on V_{BG} is distinct. Likewise, the dependence of Vₚₕ on V_{TG} also critically depends on the excitation light polarization. Moreover, the initial and final states in an optical transition are closely related to the incident photon energy, which leads to the wavelength dependence of Vₚₕ. Lastly, the power of light can also be deduced from Vₚₕ since both polarization dependent and independent components are linearly proportional to the power. Therefore, by evaluating Vₚₕ and its gate dependence of an incident light, it is possible to read out its polarization, wavelength and power. The power and polarization state can be described by the well-known Stokes parameters, S₀=I, S₁=Ip cos(2ψ)cos(2χ), S₂=Ip sin(2ψ)cos(2χ) and S₃=Ip sin(2χ), where I is the incidence power, p is the degree of polarization, ψ and χ are the orientation and ellipticity angles, respectively.

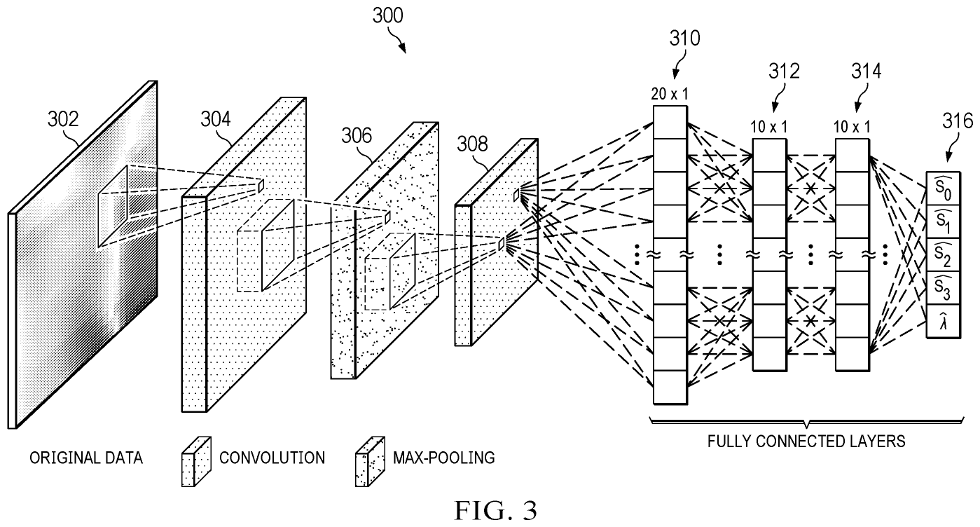

Decoding the Stokes parameters and wavelength from a measured Vₚₕ mapping is not trivial. Here the polarization state, power and wavelength of unknown incident light are all encoded in its 2D Vₚₕ mapping implicitly. We resort to convolutional neural network (CNN) to decipher the physical properties of incident light, since a CNN is most suitable for the interpretation of 2D images. The structure of CNN is shown in FIG. 3.

In the present example, the input layer 302 of CNN 300 is a mapping matrix comprising 20 by 26 Vₚₕ values measured at different combinations of V_{TG} and V_{BG}. The hidden layers comprise a first convolutional layer 304, a maximum pooling layer 306, a second convolutional layer 308, and then three fully connected layers 310, 312, 314. The output layer 316 provides a five-component vector (predicted values) including four scaled Stokes parameters (Ŝ₀, Ŝ₁, Ŝ₂, Ŝ₃) and a wavelength label \hat{λ} set to be −1 and 1 for 5 μm and 7.7 μm, respectively (Methods). The training and validation datasets consist of 9100 Vₚₕ mappings generated from 91 measured original sets and their corresponding output vectors (Methods). In the training process, a loss function, i.e., the mean squared error (MSE) between the measured and predicted values of the output vector plus 12-norm regularization terms, is minimized using the Adam optimizer. The MSEs decrease significantly to around 2×10⁻³ for both sets as the number of training epochs increases.

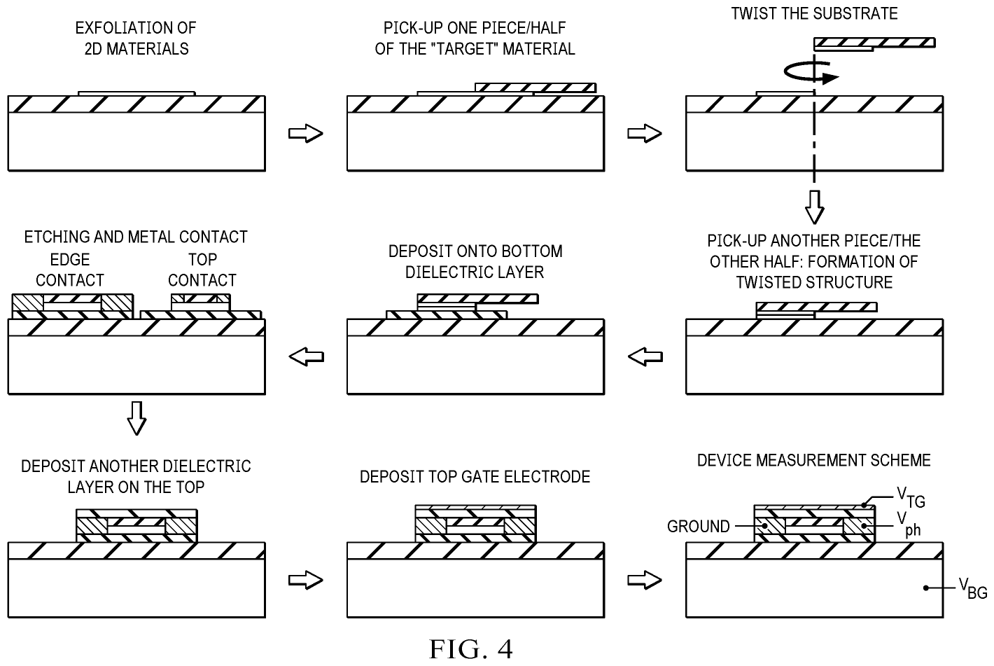

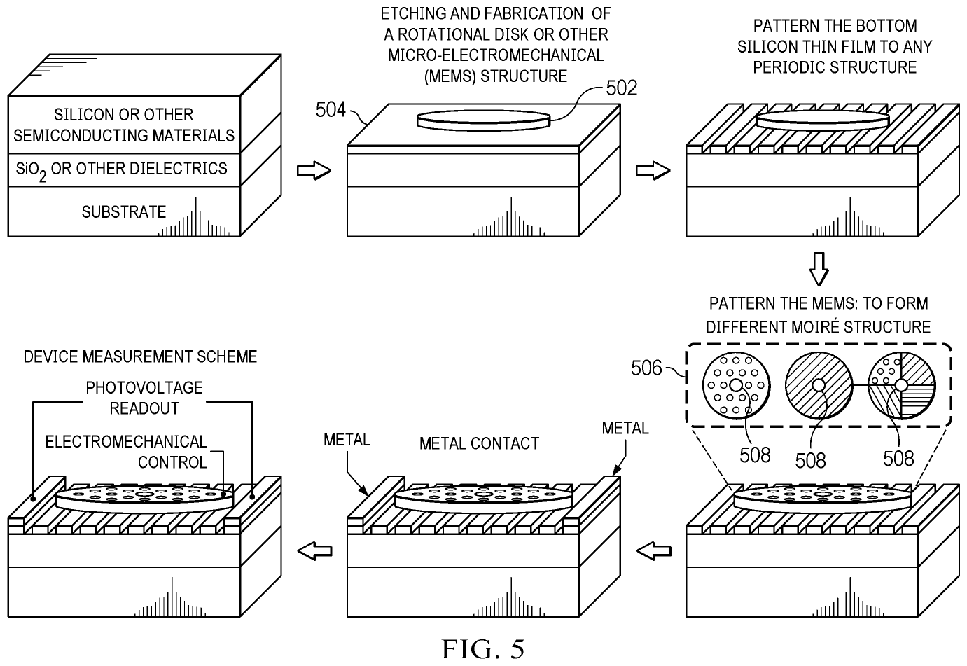

FIG. 4 depicts a side cross-section view of a sequence for manufacturing a photodetector in accordance with an illustrative embodiment. FIG. 5 depicts a perspective view of a sequence for manufacturing a photodetector in accordance with an illustrative embodiment. The key components include a micro-electromechanical (MEMS) actuator 502 (the rotary disk) and an underneath layer of the thin film 504, both made from the same semiconducting materials (silicon, germanium, etc.). The thin film 504 is patterned into any periodic structure. The actuator 502 is a rotary disk with a periodic pattern or several sectors of periodic patterns 506. The MEMS actuator 502 can rotate freely (suspended and supported by the bearing 508 at the center) or with little friction (unsuspended). The moiré pattern formed by the actuator and the underneath patterned thin film can lead to an electrical response which is dependent on the light polarization. The tuning of the response is realized by applying an electro-static or -alternating control voltage, through the electromechanical coupling to the actuator which rotate it at a certain speed.

The hBN encapsulated TDBG was fabricated using a “tear-and-stack” dry-transfer technique. Half of an AB-stack graphene bilayer was first teared by a hBN flake, then rotated by ˜1.3° and used to pick up the remaining part. The entire heterostructure hBN/TDBG/hBN was placed on SiO₂/Si substrate and then etched into desirable shapes. Electrical contacts were made along the edges with Cr/Au (3 nm/47 nm). Another hBN flake and monolayer graphene were transferred onto the fabricated device, serving as an additional dielectric layer for gating and the top gate electrode.

A dual-gate two-probe scheme was used for photovoltage measurements. The two gate voltages V_{TG} and V_{BG}, applied to the top monolayer graphene and degenerately doped Si substrate, respectively, can independently control the carrier concentration n and displacement field D in TDBG through the following relations, n=−(C_{TG}(V_{TG}−V_{TG,0})+C_{BG}(V_{BG}−V_{BG,0}))/e and D=(−C_{TG}(V_{TG}−V_{TG,0})+C_{BG}(V_{BG}−V_{BG,0}))/2ε₀, here C_{TG}(C_{BG}), V_{TG,0}(V_{BG,0}), e and ε₀ are the top (back) gate capacitance, top (back) offset voltage, elementary charge and vacuum permittivity, respectively. The device was placed in a cryostat filled with argon gas for variable temperature measurements down to 79 K. Infrared light (at 5 or 7.7 μm) from a quantum cascade laser first passed through a half-wave plate and/or a quarter-wave plate at the corresponding wavelength, then was chopped by an optical chopper at 967 Hz and finally focused on the sample by an infrared microscope. Photovoltage was collected without an external in-plane bias using a lock-in amplifier with reference to the chopping frequency. States of the light polarization described by χ and ψ in the polarization ellipse were measured by a commercial polarizer and a mercury cadmium telluride (MCT) infrared detector. Specifically, the polarizer was used to detect the direction of the major axis of the polarization ellipse. The angle between it and the photovoltage collecting direction defined the orientation angle ψ. By rotating the polarizer and recording the maximum Iₘₐₓ and minimum Iₘᵢₙ values from the readings of the MCT detector, we obtained the absolute value of |χ|=arctan (Iₘᵢₙ/Iₘₐₓ)^{1/2}. The sign of χ was deduced by examining the angle α between the polarization direction of the incident linearly polarized light and the fast axis of the quarter-wave plate. For 0<α<90°, χ>0 and for 90<α<180°, χ<0. The incidence power S₀ was obtained by measuring the total power under a microscope and the beam profile. The measurement error was estimated to be δS₀/S₀=10%. The other three Stokes parameters S₁−S₃ were obtained using the measured ψ, χ and the relations S₁/S₀=p cos(2ψ)cos(2χ), S₂/S₀=p sin(2ψ)cos(2χ) and S₃/S₀=p sin(2χ). In this work p=1 since polarized laser light was used. We further took the finite difference to estimate the measurement errors in these quantities. The error in the orientation angle was δψ=3° from the uncertainty in measuring the direction of the major axis of the polarization ellipse. The error in the ellipticity angle χ was given by δχ=(S₃/S₀)\sqrt{2}δI/4I, in which δI/I=δIₘₐₓ/Iₘₐₓ=δIₘᵢₙ/Iₘᵢₙ≈10% from the fluctuation of the intensity values read out by the MCT detector.

The CNN 300 used in this work was developed based on Tensorflow library and Keras interface. In CNN 300, the dot product of a learnable filter and its receptive field (the squares in the previous layers) produces a new element in the convolutional layers 304, 308, and performing the convolution gives us the whole layer. The max-pooling layer 306 selects maximum values in the corresponding field as its elements, which retain the major features of data and reduce their dimensions. The weight and bias parameters in convolutional layers 304, 308 and fully connected layers 310-314 are optimized in the training process through back propagation. Specifically, the first convolutional layer 304 comprises 32 kernels (filters), with a size of 5 by 5. The maximum pooling layer 306 had a pool size of 2 by 2. The second convolutional layer 308 had 16 kernels, with a size of 3 by 3. The rectified linear activation function (ReLU) was used for all hidden layers, and the hyperbolic tangent function was utilized for the output layer. L2-norm regularizations were applied to the convolutional layers 304, 308 and fully connected layers 310-314, and both regularization coefficients were chosen to be 10⁻⁴ based on the performance in cross validation. The CNN 300 outputs Ŝᵢ (i=0, 1, 2, 3) given by the hyperbolic tangent activation function were within a range from −1 to 1. We used Ŝ₀=S₀/20-1, Ŝᵢ=Sᵢ/S₀, i=1, 2, 3 to map them to −1 to 1. \hat{λ} is set to be −1 and 1 for 5 μm and 7.7 μm incidence lights, respectively. We measured 91 original Vₚₕ mappings for training and validation, and their corresponding output vectors were calculated based on the equations above. To expand the training and validation sets, we applied linear extrapolation and added random noises to generate a total of 9100 Vₚₕ mappings based on the original 91 measured mappings, and they are randomly split into the training set (90%) and the validation set (10%). The extrapolation was appropriate since the overall Vₚₕ scaled linearly with the excitation power. These techniques were widely employed in machine learning when a larger training set was desired. Acquiring more training data was expected to further improve the performance. In the training process, a loss function is minimized using the Adam optimizer. The loss function in our case is the mean squared error (MSE) between the measured and predicted values of the output vector plus 12-norm regularization terms. The directly measured polarization state, wavelength, and power (as discussed in the last section) are used as the ground truth in the training. After each epoch, the MSEs are calculated separately for the training and validation datasets.

The following Hamiltonian for the AB-AB TDBG was used for calculating its band structures and nonlinear conductivity tensors:

$$H = ( \begin{matrix}{h}^{-} + \frac{Δ}{2} & {t}^{-} & 0 & 0 \\ {t}^{-} & {h}^{-} + \frac{Δ}{6} & T ( r ) & 0 \\ 0 & {T}^{†} ( r ) & {h}^{+} - \frac{Δ}{6} & {t}^{+} \\ 0 & 0 & {t}^{+} & {h}^{+} - \frac{Δ}{2}\end{matrix} ) ,$$

where h^{±} are the low-energy effective Hamiltonians of monolayer graphene near the K point, t^{±} are the inter-layer couplings within each AB bilayer graphene, and Δ is the inter-layer potential difference. In this model,

$${h}^{\pm } = ℏ {v}_{0} ( \begin{matrix}0 & ( {q}_{x} - {iq}_{y} ) {e}^{\pm i θ / 2} \\ ( {q}_{x} + {iq}_{y} ) {e}^{∓ i θ / 2} & 0\end{matrix} ) and {t}^{\pm } = ( \begin{matrix}- {v}_{4} {π}^{\pm †} & - {v}_{3} {π}^{\pm } \\ {t}_{1} & - {v}_{4} {π}^{\pm †}\end{matrix} ) ,$$

with

$${v}_{i} = \frac{\sqrt{3} \vert {t}_{i} \vert a}{2 ℏ} ,$$

a the graphene lattice constant,

$${π}^{\pm } = {ke}^{i ( {θ}_{k} ∓ \frac{θ}{2} )} ,$$

θₖ the momentum orientation angle, and θ the TDBG twist angle. The twisted bilayer part follows the standard Bistritzer-MacDonald continuum model, with the inter-layer AA and AB couplings respectively expressed as w_{AA}=(−0.1835t₁²+1.036t₁−0.06736)/3, w_{AB}=t₁/3. In our calculations, θ=1.2°, to =−3.100 eV, t₁=0.360 eV, t₃=0.283 eV, and t₄=0.138 eV were used. Moreover, a total of 81 moiré reciprocal lattice points were used, resulting in a 648×648 Hamiltonian matrix at each mBZ momentum per spin valley.

With summation notation, the rectified nonlinear current density \vec{J} is related to the electric fields \vec{E} through a third-rank conductivity tensor as follows:

$${J}_{i} = {χ}_{ijk} ( 0 ; - ω , ω ) {E}_{j} ( - ω ) {E}_{k} ( ω ) = {χ}_{ijk} ( 0 ; - ω , ω ) {{E}_{j} ( ω )}^{*} {E}_{k} ( ω ) ,$$

where i,j,k={x,y,z}. χᵢⱼₖ vanishes for inversion symmetric systems. χᵢⱼₖ can be decomposed into its real ( [symbol] ) and imaginary ( [symbol] ) parts, which are symmetric and anti-symmetric respectively in the last two indexes. The current density can then be written as⁴⁷

$${J}_{i} = {σ}_{ijk} ( {E}_{j} ( ω ) {{E}_{k} ( ω )}^{*} + {{E}_{j} ( ω )}^{*} {E}_{k} ( ω ) ) / 2 + i {{γ}_{il} ( {\vec{E}}^{*} ( ω ) \times \vec{E} ( ω ) )}_{l} ,$$

where σᵢⱼₖ= [symbol] (χᵢⱼₖ), and γᵢₗ= [symbol] (χᵢⱼₖ)/2 is a second-rank pseudo-tensor composed of the anti-symmetric part of χᵢⱼₖ. The two separated terms are respectively responsible for linear and circular BPVE.

We first focus on the intrinsic shift current contribution to the linear BPVE. For linearly polarized light with its electric field polarized in the Ĵ direction, the conductivity tensor can be expressed as

$${σ}_{ijj} ( 0 ; ω , - ω ) = \frac{π {e}^{3}}{{ℏ}^{2}} \int \frac{{d}^{2} k}{{( 2 π )}^{2}} {\sum }_{n , m} {f}_{nm} ( {r}_{mn}^{i} {r}_{nm ; i}^{j} ) δ ( {ω}_{nm} - ω ) ,$$

where fₙₘ is the difference in Fermi occupation, rₙₘⁱ=i [symbol] n|∂ₖ_{ᵢ}|m [symbol] is the non-abelian Berry connection, r_{nm;i}^{j}=∂ₖ_{ᵢ}rₙₘ^{j}−i(rₙₙⁱ−rₘₘⁱ) rum is the generalized derivative, and ℏωₙₘ=ℏωₙ−ℏωₘ is the energy difference between the n-th and m-th bands. ℏω is the energy of the irradiation photons, and the integration is carried out in the first mBZ.

The pseudo-tensor for the intrinsic injection current rate can be calculated by

$${β}_{ij} ( ω ) = \frac{π {e}^{3}}{{ℏ}^{2}} {ϵ}_{jlk} \int \frac{{d}^{2} k}{{( 2 π )}^{2}} {\sum }_{n , m} {f}_{nm} {Δ}_{nm}^{i} {r}_{nm}^{l} {r}_{mn}^{k} δ ( {ω}_{nm} - ω ) .$$

Under uniaxial heterostrain (that breaks C_{3z} symmetry and induces circular BPVE), the graphene Dirac cones are shifted such that k_{l,ξ}→k_{l,ξ}=[ [symbol] +∈ₗ^{T}][q−D_{l,ξ}], where D_{l,ξ}=[ [symbol] −∈ₗ^{T}]K_{l,ξ}−ξAₗ gives the positions of the Dirac points,

$${A}_{l} = \frac{\sqrt{3} ζ}{2 a} ( {ϵ}_{l}^{xx} - {ϵ}_{l}^{yy} , - 2 {ϵ}_{l}^{xy} )$$

is the induced gauge field, ξ and l denote the valley and layer degrees of freedom, and

$${ϵ}_{l} = {ℱ}_{l} ε ( \begin{matrix}- {cos}^{2} ϕ + v {sin}^{2} ϕ & ( 1 + v ) cos ϕsinϕ \\ ( 1 + v ) cos ϕsinϕ & v {cos}^{2} ϕ - {sin}^{2} ϕ\end{matrix} ) .$$

We assume that the bottom (b) two and top (t) two layers of the TDBG are strained in the opposite directions, i.e., [symbol] _{b,t}=‡^{1/2}, but with the same strength ε. In the simulations, the graphene hopping modulus factor ζ=3.14, the graphene Poisson ratio v=0.165, ε=0,0.1%, 0.6%, and the strain direction ϕ=30° were used.

### Nonlinear Conductivity Calculations

In evaluating the conductivity tensor σᵢⱼⱼ(0;ω,−ω), a ‘sum rule’ was used such that the differentiations act on the Hamiltonian matrix instead of the Dirac kets:

$${r}_{nm}^{i} = \frac{{v}_{nm}^{i}}{i {ω}_{nm}} , {r}_{nm ; j}^{i} = \frac{i}{{ω}_{nm}} [ \frac{{v}_{nm}^{i} {Δ}_{nm}^{j} + {v}_{nm}^{j} {Δ}_{nm}^{i}}{{ω}_{nm}} - {w}_{nm}^{ij} + {\sum }_{p \neq n , m} ( \frac{{v}_{np}^{i} {v}_{pm}^{j}}{{ω}_{pm}} - \frac{{v}_{np}^{j} {v}_{pm}^{i}}{{ω}_{np}} ) ] ,$$

with vₙₘⁱ= [symbol] uₙ|∂ₖ_{ᵢ}H|uₘ [symbol] /ℏ, Δₙₘⁱ=∂ₖ_{ᵢ}ωₙₘ=vₙₙⁱ−vₘₘⁱ, and wₙₘⁱ= [symbol] uₙ|∂ₖ_{ᵢ}ₖ_{ⱼ}²H|uₘ [symbol] /ℏ. Moreover, the Dirac delta function was smeared by a Gaussian function g with a smearing parameter W as follows:

$$g ( k ) = \frac{1}{\sqrt{2 π} W} exp ( \frac{- {( ω - {ω}_{mn} ( k ) )}^{2}}{2 {W}^{2}} ) .$$

Given that the moiré bands can be extremely flat, the adaptive smearing approach was empolyed. In this approach, the smearing parameter is state-dependent, given by

$${W}_{nm} ( k ) = \vert \frac{\partial {ω}_{n}}{\partial k} - \frac{\partial {ω}_{m}}{\partial k} \vert Δ k ,$$

where Δk is the distance between the neighbouring sampling points. The mBZ was discretized into 346×346 sampling points, which are sufficiently dense to ensure convergence of the calculations. Contributions to σ were ignored if |ω−ωₘₙ(k)|>6W(k).

In our work, only in-plane photovoltages were collected, the light was at normal incidence to the material, we find that \vec{J} can be expressed as

$$( \begin{matrix}{J}_{x} \\ {J}_{y}\end{matrix} ) = ( \begin{matrix}{σ}_{x x x} & {σ}_{x x y} & {σ}_{x y x} & {σ}_{x y y} \\ {σ}_{yxx} & {σ}_{yxy} & {σ}_{yyx} & {σ}_{yyy}\end{matrix} ) ( \begin{matrix}{E}_{x}^{2} \\ {E}_{x} {E}_{y} \\ {E}_{y} {E}_{x} \\ {E}_{y}^{2}\end{matrix} ) .$$

In the experimental setup, the current or the electric field directions may not be aligned with the principal axes of the crystal coordinate system (i.e., the x- and y-axes used above), due to the difficulty in knowing the crystallographic axes of TDBG, but with an angle φ measured from the x-axis. In this device coordinate system, denoted by the prime symbol, the current and electric field are related to those in the crystal coordinate system by the following rotations

$$( \begin{matrix}{J}_{x}^{′} \\ {J}_{y}^{′}\end{matrix} ) = R ( \begin{matrix}{J}_{x} \\ {J}_{y}\end{matrix} ) , ( \begin{matrix}{E}_{x}^{′} \\ {E}_{y}^{′}\end{matrix} ) = R ( \begin{matrix}{E}_{x} \\ {E}_{y}\end{matrix} ) , ( \begin{matrix}{E}_{x}^{′2} \\ {E}_{x}^{′} {E}_{y}^{′} \\ {E}_{y}^{′} {E}_{x}^{′} \\ {E}_{y}^{′2}\end{matrix} ) = {R}^{′} ( \begin{matrix}{E}_{x}^{2} \\ {E}_{x} {E}_{y} \\ {E}_{y} {E}_{x} \\ {E}_{y}^{2}\end{matrix} ) ,$$

where the rotations R and R′ are given by

$$R = ( \begin{matrix}cos ϕ & sin φ \\ - sin φ & cos φ\end{matrix} ) ,$$

$${R}^{′} = ( \begin{matrix}{cos}^{2} φ & cos φ sin φ & cos φ sin φ & {sin}^{2} φ \\ - cos φ sin φ & {cos}^{2} φ & - {sin}^{2} φ & cos φ sin φ \\ - cos φ sin φ & - {sin}^{2} φ & {cos}^{2} φ & cos φ sin φ \\ {sin}^{2} φ & - cos φ sin φ & - cos φ sin φ & {cos}^{2} φ\end{matrix} ) .$$

In the presence of a C_{3z} symmetry in AB-AB TDBG, there is a symmetry constraint σ=R⁻¹σR′ with φ=2π/3 that leads to

$$σ = ( \begin{matrix}{σ}_{x x x} & - {σ}_{yyy} & - {σ}_{yyy} & - {σ}_{xxx} \\ - {σ}_{yyy} & - {σ}_{xxx} & - {σ}_{xxx} & {σ}_{yyy}\end{matrix} ) .$$

There are only two independent elements for φ. For an electric field of magnitude E that makes an angle ψ above the x-axis, the photocurrent density J exhibits a 2ψ dependence with respect to the optical field polarization:

$${J}_{x} = {E}^{2} ( {σ}_{x x x} cos 2 ψ - {σ}_{y y y} sin 2 ψ ) , {J}_{y} = {E}^{2} ( - {σ}_{x x x} sin 2 ψ - {σ}_{y y y} cos 2 ψ ) .$$

It follows that the polarization for the maximum or minimum photovoltage (V∝J) depends on the ratio between σₓₓₓ and σ_{yyy}; it changes with the top/bottom gate voltages in our experiments. In the numerical calculations of σₓₓₓ and σ_{yyy}, the crystal coordinate system is used. In the device coordinate system, if the x′-axis (the photocurrent/photovoltage collection direction) makes an angle φ with the x-axis, J_{x′}=Jₓ cos φ+J_{y} sin φ and J_{y′}=−Jₓ sin φ+J_{y} cos φ, equivalent to a change of variable 2ψ→2ψ+σ in the current density equations above.

With an extra mirror symmetry [symbol] ₓ (the symmetry group C_{3z} is enlarged to C₃ᵥ), any element in the conductivity tensor that contains odd number of index x should vanish, resulting in

$$σ = ( \begin{matrix}0 & - {σ}_{yyy} & - {σ}_{yyy} & 0 \\ - {σ}_{yyy} & 0 & 0 & {σ}_{yyy}\end{matrix} ) .$$

In this case, there is only one independent non-zero element, and the photocurrent is given by

$${J}_{x} = - {E}^{2} {σ}_{y y y} sin 2 ψ , {J}_{y} = - {E}^{2} {σ}_{y y y} cos 2 ψ ,$$

In contrast to the C_{3z} case, the polarization for the maximum or minimum photovoltage does not change with σ_{yyy} or the top/bottom gate voltages in our experiments. The analysis for the mirror symmetry [symbol] _{y} is similar. Note that both mirror symmetries are broken in AB-AB TDBG.

In AB-AB TDBG, there is a C₂ₓ symmetry, besides the C_{3z} symmetry. As a result, any element in the conductivity tensor with odd number of index y should vanish, leaving only one independent non-zero element:

$$σ = ( \begin{matrix}{σ}_{x x x} & 0 & 0 & - {σ}_{x x x} \\ 0 & - {σ}_{x x x} & - {σ}_{x x x} & 0\end{matrix} ) .$$

Without any external bias to break the C₂ₓ symmetry, the polarization for the maximum or minimum photovoltage does not change with σₓₓₓ. However, the top/bottom gate voltages in our experiments break the C₂ₓ symmetry. The analysis for the C_{2y} symmetry is similar.

A C_{2z} symmetry is present in TBG but not in TDBG or other graphene moiré system. As a consequence of the C_{2z} symmetry, any element in the conductivity tensor with odd number of index x or y should vanish. Therefore, σ=0 in TBG.

For circularly polarized light at normal incidence to a 2D material, \vec{E}(ω)×\vec{E}*(ω) is along z direction. As a result, in-plane injection current cannot be generated in TDBG, given its intrinsic C_{3z} symmetry. However, strain effects and interaction-induced nematic phase may weakly break C_{3z} symmetry and account for our observation of the non-vanishing circular BPVE in TDBG. The exact origin of the observed circular BPVE deserves further research.

Detailed discussions on BPVE under different symmetries and associated calculations can be found in Supplementary Information.

The BPVE in TDBG is unique in the following three aspects. First, the moiré-engineered C_{3z} symmetry allows for the aforementioned σₓₓₓ and σ_{yyy} to be nontrivial and independent. This gives rise to linear BPVE with electrically tunable amplitude and phase in the Vₚₕ oscillation. Notably, an additional symmetry such as C₂ₓ (in TDBG with ΔV=0), C_{2z} (present in TBG but absent in all other graphene moiré systems), or vertical mirror (in non-moiré graphene systems) dictates σₓₓₓ or/and σ_{yyy} to vanish, not to mention the inversion (Supplementary Information). Second, both the amplitude and the phase of the BPVE response in TDBG are strongly tunable by external electric fields because ΔV can largely modify the band structure and wavefunctions of TDBG and thus its quantum geometric properties; varying E_{F} in TDBG can select moiré minibands with different quantum geometric properties for the generation of BPVE. Third, the widely tunable BPVE in TDBG is strong in a broad spectral range. Unlike any pristine material (Supplementary Information), the large inter-layer moiré potential and the moiré-induced Brillouin zone folding in TDBG lead to abundant states from multiple minibands available for the inter-band optical transitions over a wide energy range. This is manifested in the strongly oscillating behavior of the calculated σₓₓₓ and σ_{yyy} with ℏω, since even a small change in ℏω can alter the optical transitions dramatically. To summarize, the demonstrated BPVE is universal to graphene moiré systems with no C_{2z} symmetry, and TDBG is the simplest.

To read out the information of an unknown incident light from a Vₚₕ mapping is challenging, because light polarizations are represented by the continuous Stokes vector, and because wavelength and power are also continuous (though in this work we used only two wavelengths). Direct quantitative modelling of the nonlinear photoresponse to match the experimentally measured Vₚₕ is not feasible, due to the inevitable complexity in TDBG devices such as lattice relaxation and extrinsic scattering. Inferring the information of the incident light based on analytical fittings is not practical because it requires numerous polarization-dependent measurements at multiple different gate biases, wavelengths, and power levels for a reliable assessment. Moreover, to extract Stokes parameters and wavelength by directly comparing the Vₚₕ mapping under a testing light with those already measured under the excitation of light with known information is highly unreliable, as the number of possible polarization states is in principle infinite and the incidence wavelength and power can also vary. By contrast, machine learning methods are well known for the capability of completing specific tasks without being specifically programmed. Machine learning techniques have been used for many applications including imaging recognition, ultrafast optics, and analysis of the angular momentum of light. Among all machine learning methods, the convolutional neural network (CNN) is most suitable for the interpretation of 2D images, such as object recognition and classification, and indeed the polarization state, power, and wavelength of each incident light are all encoded uniquely in its 2D Vₚₕ mapping. Introducing convolutional layers to the neural network greatly reduces the number of training parameters and retains the essential features in the input data. After the training of CNN with a reasonably large number of experimentally measured Vₚₕ mappings under the incident lights with known polarizations, powers, and wavelengths, the CNN can predict these continuous variables based on a new Vₚₕ mapping under the excitation of an unknown light.

To confirm the presence of the superlattice-induced insulating state and thus the formation of the TDBG moiré superlattice, we show the temperature-dependent resistance (R) at selected carrier concentrations (n) and displacement fields (D) in TDBG D1. Six sets of gate biases (marked by colored dots) are selected, and their ln(R) as functions of 100/T were plotted. For the resistances measured at charge neutrality (n=0) and at D=0.54 V/nm and −0.54 V/nm, we observe insulating behaviors, i.e., R increases with a decreased temperature, implying the band gap openings at charge neutrality under D fields. Similarly, at n=3.2×10¹² cm⁻² and small displacement fields, D=0 and 0.15 V/nm, we also observe insulating behaviors, indicating the presence of the superlattice-induced gap. Moreover, at the same concentration n=3.2×10¹² cm⁻² but a large field, D=0.6 V/nm, the resistance increases slightly with elevated temperature. This observation implies that the superlattice gap is closed and the TDBG is metallic. In addition, introducing more electrons also turns the TDBG into a metallic state again. These observations are consistent with our theoretical results and other previously reported experiments, supporting our conclusion that the electron-side superlattice-induced gap exists at n=3.2×10¹² cm⁻² and the TDBG moiré superlattice is successfully formed. We note that the hole-side full filling n=−nₛ is not evident in the TCR mapping, and that similar features of a less insulating hole-side superlattice gap were also reported before.

As discussed above, the amplitude and the phase of the Vₚₕ oscillation curve are (V_{c}²+Vₛ²)^{1/2} and ψ′₀=arctan (V_{c}/Vₛ), respectively, which lead to drastically different photoresponse for the two incident wavelengths. This wavelength dependent Vₚₕ allows for the wavelength detection in our tunable TDBG photodetector leveraging CNN.

The amplitude of Vₚₕ oscillation, (V_{c}²+Vₛ²)^{1/2}, linearly depends on the incident power for all four sets of gate voltage combinations in this experiment. The linear-in-power dependence confirms the second-order nature of the polarization-dependent Vₚₕ, consistent with previous observations of BPVE. Moreover, we examine the power dependence of the overall Vₚₕ, including both the polarization-dependent (V_{c}²+Vₛ²)^{1/2} and polarization-independent V_{const} components. A linear relation between the overall Vₚₕ and the incident power is evident for different polarization angles and gate voltages. This feature implies that the polarization-independent component V_{const} is also linearly dependent on the power, consistent with our argument that it mainly comes from the photothermal effect which depends linearly on the incident power (as discussed in next section). In addition, this linear dependence of Vₚₕ on power provides the basis for the expansion of the training and validation data sets as discussed above.

In our Vₚₕ measurements, a knife-edge technique is used to determine the size of the laser spot and we assume a Gaussian profile for the intensity distribution. The standard deviation σ of the laser intensity profile is ˜7 μm and ˜11 μm for 5 μm and 7.7 μm incident light, respectively. Such beam spots are larger than our TDBG photodetector (3×3 μm²). Although a large beam spot can reduce the contribution from the photo-thermal effect due to the enhanced light intensity uniformity within the device area, the photo-thermal voltage arising from non-uniform illumination can still play a role as discussed in previous works. As discussed below, the photo-thermal effect produces a polarization-independent background in the measured photoresponse Vₚₕ, which is minimized when aligning the light spot with the center of the device.

In general, the photo-thermal voltage V_{Th} can be modeled as V_{Th}=(S₂−S₁)ΔT. Here, S_{1,2} is the Seebeck coefficient of material 1 or 2, and ΔT is the temperature difference induced by light illumination. In our TDBG photodetector, the photothermal effect induced photovoltage mainly occurs at the two contact regions, given by V_{Thermal,±}=±(S_{TDBG}−Sₘₑₜₐₗ)ΔT, because of the difference in the Seebeck coefficients of the TDBG and metal electrodes. Ideally, when the beam spot is placed at the center of the TDBG, the overall voltage induced by the photothermal effect at the two metal-TDBG interfaces, V_{Thermal}=V_{Thermal,+}+V_{Thermal,-}, vanishes in a symmetric device because of the cancellation of the photo-thermal voltages at the two interfaces. However, a deviation of the beam spot from the device center, together with unintentional asymmetry in the contact regions, can lead to a non-vanishing V_{Thermal} in the measured Vₚₕ. Since the photo-thermal voltage is proportional to the local laser power, the dependence of V_{Thermal} on the beam spot position x with respect to the center of the device along the voltage collecting path can be modelled by

$${V}_{Thermal} = {A}_{1} ( {e}^{- \frac{{( x - {x}_{0} )}^{2}}{2 {w}^{2}}} - {e}^{- \frac{{( x + {x}_{0} )}^{2}}{2 {w}^{2}}} ) .$$

Here, x₀=1.5 μm is half of the length of the device, x is the displacement of the beam spot with respect to the center of the device, A₁ is proportional to the absorbed power of the incident light, and w˜7 μm is the fitting parameter representing the standard deviation of the Gaussian beam profile along x-axis. This model accounts for the contributions from the two interfaces and is thus an odd function of x. In contrast, at a fixed polarization, the BPVE photovoltage V_{BPVE} is proportional to the light power and can be modeled by

$${V}_{BPVE} = {A}_{2} {e}^{- \frac{{x}^{2}}{2 {w}^{2}}} ,$$

which is an even function of x. The photo-thermal effect can contribute to Vₚₕ in the measured mappings, due to the imperfect beam alignment with respect to the device center and possible device asymmetry. However, it will not affect the device performance due to its insensitivity to polarization and its relatively small amplitude.

We note that the photo-thermal effect in TDBG is expected to be independent of polarization, since the absorption of TDBG is isotropic. Thus, the polarization-independent components in the measured Vₚₕ can be mainly attributed to V_{Thermal} in our TDBG devices. This property is very different from that of the previously reported Weyl semimetal systems, in which the absorptions can be significantly different along different directions, giving rise to a polarization dependent V_{Thermal}.

The overall Vₚₕ shows a strong temperature dependence and decreases to nearly zero above 250 K. By plotting (V_{c}²+Vₛ²)^{1/2} as a function of the temperature, we observe a ˜10 times smaller oscillation amplitude from 79 K to 250 K at all sets of gate voltage combinations. Such a reduction in BPVE signal can be attributed to the shortening of the relaxation time of hot carriers excited by photons due to stronger scatterings at higher temperatures. At a steady state, the nonlinear photoresponse is proportional to the relaxation time and decreases with increased temperature, as reported by the previous works on BPVE in Weyl semimetals. Besides, thermal smearing of resonant optical transitions could also reduce the nonlinear photoresponse at higher temperatures.

For a TDBG with a twist angle ˜1.1° (TDBG D2), in the Vₚₕ mappings taken at different light polarizations, there is a strong tuning effect of Vₚₕ both in the magnitude and polarity by the gate biases, similar to that in the device (D1) in FIG. 1. Each of the Vₚₕ mappings taken at a certain polarization shows a distinct pattern which encodes the information of the polarization state. Measured Vₚₕ can be well fitted by Vₚₕ=V_{c} cos(2ψ)+Vₛ sin(2ψ)+V_{const}. A strong tuning effect of V_{c} and Vₛ by gate biases is evident, and it is consistent with our theoretical prediction that two independent, non-vanishing, tunable nonlinear conductivity elements exist in TDBG. Amplitude of Vₚₕ, i.e., (V_{c}²+Vₛ²)^{1/2}, as a function of the power on device, confirms the second-order nature of the photoresponse. In addition, the amplitude of Vₚₕ strongly depends on the temperature. In short, all the major observations on the linear bulk photovoltaic effect are consistent with those measured from D1.

We have calculated the nonlinear conductivity elements, σₓₓₓ and σ_{yyy}, in TDBG with twist angles of 1.2°, 1.4°, 1.6° and 1.8°. Because the band structure of TDBG depends on the twist angle, the nonlinear conductivity elements determined by the quantum geometric properties and available interband transitions are tunable by the twist angle. The conductivity elements are substantial for all four twist angles. In short, the twist angle is another degree of freedom to tune the BPVE in TDBG.

In our work, the BPVE can be largely tuned by electrical biases, and thus the extrinsic responsivity Rₑₓ, defined as the amplitude of the Vₚₕ oscillation, (V_{c}²+Vₛ²)^{1/2}, at (V_{BG}, V_{TG}) divided by the power on the device, is tunable. The maximum Rₑₓ in our measurement reaches ˜3.7 V/W at 7.7 μm in TDBG D1, ˜3.1 V/W at 5 μm in TDBG D1, and ˜3.3 V/W at 5 μm in TDBG D2. These values are considerable, given that our observed BPVE is a second-order photoresponse, and even comparable to the regular first-order photoresponse in monolayer graphene with a similar structure. According to our theoretical calculations, the BPVE should remain substantial in a wide range of spectrum and peaks in the terahertz regime. (Strong shift current response at terahertz frequencies has also been theoretically predicted in simple TBG with broken C_{2z} symmetry.) This observation shows the feasibility of constructing a high-sensitivity, broadband intelligent sensor based on TDBG.

The polarization state of an incident light can be represented by the Stokes parameters (S₁/S₀, S₂/S₀, S₃/S₀), while the CNN predicted values are ( [symbol] , [symbol] , [symbol] ). Thus, any two unknown polarization states whose Stokes parameters differences are smaller than (ΔS₁, ΔS₂, ΔS₃)=(S₁/S₀− [symbol] , S₂/S₀− [symbol] , S₃/S₀− [symbol] ) cannot be accurately distinguished by our scheme. We notice that (ΔS₁, ΔS₂, ΔS₃) depend on the position of the polarization state on the Poincare sphere, i.e., the actual values of (S₁/S₀, S₂/S₀, S₃/S₀). The complete information of (ΔS₁, ΔS₂, ΔS₃) for all measured states in our work can be read out from the projection S₁-S₂ and S₂-S₃ planes.

The utilization of CNN as a decoder, together with the tunable BPVE of TDBG as an encoder, enables the simultaneous decipherment of light polarization, power and wavelength using a single on-chip device with a sub-wavelength footprint. Although in this work we focus on mid-infrared spectral range, we expect that such nonlinear photoresponse shaped by quantum geometric properties in TDBG persists down to terahertz regime (Supplementary Information), and that the demonstrated intelligent graphene sensor can be operational from mid-infrared to terahertz. Similar nonlinear photoresponse may also be prominent at visible or near-infrared wavelengths in hetero- or homo-bilayers of transition metal dichalcogenides due to the analogous symmetry reduction and geometric properties. Our demonstration thus opens a potential avenue for on-chip intelligent light sensing in a broad spectral range.

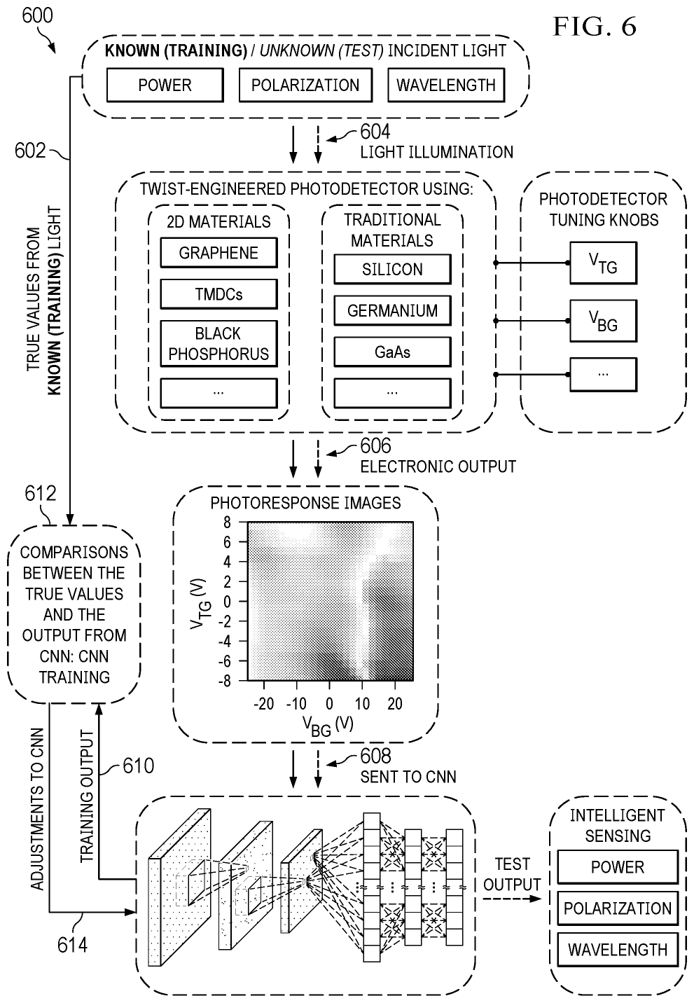

FIG. 6 depicts a flowchart for training a neural network to measure quantities of light in accordance with an illustrative embodiment. Process 600 beings by inputting a set of known data points regarding light intensity, polarization, and wavelength and corresponding photovoltage maps or photocurrent maps into a neural network as a training dataset (step 602).

A set of incident light of the known intensity, polarization, and wavelength is shined on a photodetector comprising a twisted Moiré superlattice (step 604). The photodetector is in communication with the neural network.

A set of photovoltage maps or photocurrent maps are generated as functions of voltages generated by one or more tuning controls in the photodetector that tune photovoltages or photocurrents collected by contact electrodes connected to the Moiré superlattice in response to excitement of the Moiré superlattice by the incident light (step 606). The tuning controls might comprise tuning gates. Tuning parameters for the photovoltage maps or photocurrent maps might comprise at least one of voltage, current, temperature, strain, or magnetic field.

The photovoltage maps or photocurrent maps are input into the neural network (step 608).

The neural network concurrently predicts the intensity, polarization, and wavelength of the incident light from each of the photovoltage maps or photocurrent maps (step 610).

The predicted intensity, polarization, and wavelength is compared to the known intensity, polarization, and wavelength in the set of known data points (step 612).

Parameters of the neural network are adjusted in response to predicted intensity, polarization, and wavelength that do not match the known intensity, polarization, and wavelength (step 614).

The neural network is retrained until errors of all training data reach are minimized. Process 600 then ends.

### Supplementary Information for Intelligent Infrared Sensing Enabled by Tunable Moiré Quantum Geometry

Bulk Photovoltaic Effect (BPVE), Symmetry Analysis, and their Applications to Twisted Double Bilayer Graphene (TDBG)

### 1 Introduction

The electric field in the time domain reads

$$\vec{E} ( r , t ) = {\int }_{- ∞}^{∞} \vec{E} ( r , ω ) {e}^{- i ω t} d ω , \qquad ( 1 )$$

which sums over all the monochromatic states and contains both the space and phase information. Given that \vec{E}(r,t) is real, \vec{E}(r,−ω)=\vec{E}*+(r,ω), where the asterisk denotes a complex conjugation. With summation notation, the rectified nonlinear current density \vec{J} in bulk photovoltaic effect (BPVE) is related to the electric fields \vec{E} through a third-rank conductivity tensor as follows:

$$\begin{matrix}{J}_{i} = {χ}_{i j k} ( 0 ; - ω , ω ) {E}_{j} ( - ω ) {E}_{k} ( ω ) \\ = {χ}_{i j k} ( 0 ; - ω , ω ) {E}_{j} ( ω ) * {E}_{k} ( ω ) ,\end{matrix} \qquad ( 2 )$$

where i,j,k={x,y,z}. χᵢⱼₖ vanishes for inversion symmetric systems. χᵢⱼₖ can be decomposed into its real and imaginary parts, which are symmetric and anti-symmetric respectively in the last two indexes. The current density can then be written as

$${J}_{i} = {σ}_{i j k} ( {E}_{j} ( ω ) {{E}_{k} ( ω )}^{*} + {{E}_{j} ( ω )}^{*} {E}_{k} ( ω ) ) / 2 + i {{γ}_{i l} ( {\vec{E}}^{*} ( ω ) \times \vec{E} ( ω ) )}_{l} , \qquad ( 3 )$$

where σᵢⱼₖ= [symbol] (χᵢⱼₖ), and γᵢₗ= [symbol] (χᵢⱼₖ)/2 is a second-rank pseudo-tensor composed of the anti-symmetric part of χᵢⱼₖ. The two separated terms are respectively responsible for linear and circular BPVEs, usually referred to as shift and injection photoresponses, respectively.

### 2 Linear Bulk Photovoltaic Effect

The expression of the conductivity tensor for shift current is given by

$${σ}_{i j k} ( 0 ; ω , - ω ) = \frac{i π {e}^{3}}{2 {ℏ}^{2}} \int \frac{{d}^{2} k}{{( 2 π )}^{2}} {\sum }_{n , m} {f}_{n m} ( {r}_{m n}^{j} {r}_{n m ; i}^{k} + {r}_{m n}^{k} {r}_{n m ; i}^{j} ) δ ( {ω}_{n m} - ω ) , \qquad ( 4 )$$

where fₙₘ=fₙ−fₘ=−1 is the difference in Fermi occupation between the n-th and m-th bands at zero temperature, rₙₘⁱ=i(n|∂ₖ_{ᵢ}|m) the non-abelian Berry connection, r_{nm;i}^{j}=∂ₖ_{ᵢ}rₙₘ^{j}−i(rₙₙⁱ−rₘₘⁱ)rₙₘ^{j} the generalized derivative, ℏωₙₘ=ℏωₙ−ℏωₘ the energy difference between the n-th and m-th bands, ℏω the energy of the irradiation photons, and the integration is carried out in the first Brillouin zone. For linearly polarized light with its electric field polarized in the Ĵ direction, the conductivity tensor can also be expressed as

$${σ}_{i j j} ( 0 ; ω , - ω ) = \frac{π {e}^{3}}{{ℏ}^{2}} \int \frac{{d}^{2} k}{{( 2 π )}^{2}} {\sum }_{n , m} {f}_{n m} {R}_{n m}^{i} {\vert {r}_{n m}^{j} \vert}^{2} δ ( {ω}_{n m} - ω ) \qquad ( 5 )$$

by introducing rₙₘ^{j}(k)=|rₙₘ^{j}(k)|e^{-iϕ}^{ₙₘ}^{(k)}. In this expression,

$${R}_{nm}^{i} = \frac{\partial {ϕ}_{nm}}{\partial {k}^{i}} + {r}_{nn}^{i} - {r}_{mm}^{i}$$

is the shift vector, which measures the change in the position of a wave packet after a photo-excitation, and |rₙₘ^{j}|²δ(ωₙₘ−ω) can be interpreted as the transition rate that resembles the Fermi golden rule. The conductivity tensor can also be expressed as

$${σ}_{ijj} ( 0 ; ω , - ω ) = \frac{π {e}^{3}}{{ℏ}^{2}} \int \frac{{d}^{2} k}{{( 2 π )}^{2}} {\sum }_{n , m} {f}_{nm} ( {r}_{mn}^{j} {r}_{nm ; i}^{j} ) δ ( {ω}_{nm} - ω ) . \qquad ( 6 )$$

This equation was used for numerically calculating the shift current as discussed below. Previously shift current has been evaluated theoretically in twisted bilayer graphene with broken C_{2z} symmetry based on a similar approach.

The injection current is defined as the second order response as follows

$${dJ}_{i} / dt = {{β}_{ij} ( ω ) [ {\vec{E}}^{*} ( ω ) \times \vec{E} ( ω ) ]}_{j} , \qquad ( 7 )$$

where Jᵢ is the i-th component of the photocurrent density. The pseudo-tensor β reads

$${β}_{ij} ( ω ) = \frac{π {e}^{3}}{{ℏ}^{2}} {ϵ}_{jlk} \int \frac{{d}^{2} k}{{( 2 π )}^{2}} {\sum }_{n , m} {f}_{nm} {Δ}_{nm}^{i} {r}_{nm}^{l} {r}_{mn}^{k} δ ( {ω}_{nm} - ω ) , \qquad ( 8 )$$

where Δₙₘⁱ=∂ₖ_{ᵢ}ωₙₘ measures the change in carrier velocity after a photo-excitation. As far as an in-plane current is concerned, β can be reduced to

$$( \begin{matrix}{β}_{xx} & {β}_{xy} \\ - {β}_{xy} & {β}_{xx}\end{matrix} )$$

in the presence of the C_{3z} symmetry, with only two independent elements. A mirror symmetry [symbol] ₓ or [symbol] _{y} further requires the diagonal elements to be zero. For circularly polarized light at normal incidence to a 2D material, \vec{E}(ω)×\vec{E}*(ω) is along z-direction. As a result, in-plane injection current cannot be generated in TDBG, given its intrinsic C_{3z} symmetry. However, strain effects and interaction-induced nematic phase may exist and break C_{3z} symmetry. Such a C_{3z} symmetry breaking may account for our observation of the non-vanishing injection current (circular BPVE) in TDBG.

To illustrate the circular BPVE under strain in TDBG, we calculated the pseudo tensor elements, β_{xz} and β_{yz}′ which are responsible for the in-plane photoresponse Jₓ and J_{y}, with uniaxial heterostrain ε=0, 0.1% and 0.6%. In these calculations, we used interlayer potential difference ΔV=50 meV and Fermi level E_{F}=0. The calculated results support our symmetry analysis above. Moreover, we plotted β_{xz} and β_{yz} as functions of a at incident photon energies ℏω=161 and 248 meV, corresponding to incident light wavelengths of 7.7 and 5 μm, respectively. Evidently, the absolute values of β_{xz} and β_{yz} increase with the heterostrain, i.e., the circular BPVE increases with the degree of C_{3z} symmetry breaking. At these energies (161 and 248 meV), 0.1% strain can already induce appreciable β_{xz} and β_{yz}, generating circular BPVE by weakly breaking C_{3z} symmetry.

In matrix notation, the second order photocurrent density \vec{J} is related to the electric field \vec{E} through a third-rank tensor σᵢⱼₖ as follows:

$$( \begin{matrix}{J}_{x} \\ {J}_{y} \\ {J}_{z}\end{matrix} ) = ( \begin{matrix}{σ}_{xxx} & {σ}_{xyy} & {σ}_{xzz} & {σ}_{xyz} & {σ}_{xzx} & {σ}_{xxy} \\ {σ}_{yxx} & {σ}_{yyy} & {σ}_{yzz} & {σ}_{yyz} & {σ}_{yzx} & {σ}_{yxy} \\ {σ}_{zxx} & {σ}_{zyy} & {σ}_{zzz} & {σ}_{zyz} & {σ}_{zzx} & {σ}_{zxy}\end{matrix} ) ( \begin{matrix}{E}_{x}^{2} \\ {E}_{y}^{2} \\ {E}_{z}^{2} \\ 2 {E}_{y} {E}_{z} \\ 2 {E}_{z} {E}_{x} \\ 2 {E}_{x} {E}_{y}\end{matrix} ) . \qquad ( 9 )$$

In our work, only in-plane photovoltages were collected, and the light was at normal incidence to the material, so we can remove J_{z} and E_{z}. Writing 2EₓE_{y} separately into EₓE_{y} and E_{y}Eₓ, we find that \vec{J} can be expressed as

$$( \begin{matrix}{J}_{x} \\ {J}_{y}\end{matrix} ) = ( \begin{matrix}{σ}_{xxx} & {σ}_{xxy} & {σ}_{xyx} & {σ}_{xyy} \\ {σ}_{yxx} & {σ}_{yxy} & {σ}_{yyx} & {σ}_{yyy}\end{matrix} ) ( \begin{matrix}{E}_{x}^{2} \\ {E}_{x} {E}_{y} \\ {E}_{y} {E}_{x} \\ {E}_{y}^{2}\end{matrix} ) . \qquad ( 10 )$$

Without any symmetry constraint, all matrix elements of σ are generally independent. In the experimental setup, the current or electric field directions may not be aligned with the principal axes of the crystal coordinate system (i.e., the x- and y-axes used above), due to the difficulty in knowing the crystallographic axes of TDBG, but with an angle φ measured from the x-axis. In this device coordinate system, denoted by the prime symbol, the current and electric field are related to those in the crystal coordinate system by the following rotations

$$( \begin{matrix}{J}_{x}^{′} \\ {J}_{y}^{′}\end{matrix} ) = R ( \begin{matrix}{J}_{x} \\ {J}_{y}\end{matrix} ) , ( \begin{matrix}{E}_{x}^{′} \\ {E}_{y}^{′}\end{matrix} ) = R ( \begin{matrix}{E}_{x} \\ {E}_{y}\end{matrix} ) , ( \begin{matrix}{E}_{x}^{′2} \\ {E}_{x}^{′} {E}_{y}^{′} \\ {E}_{y}^{′} {E}_{x}^{′} \\ {E}_{y}^{′2}\end{matrix} ) = {R}^{′} ( \begin{matrix}{E}_{x}^{2} \\ {E}_{x} {E}_{y} \\ {E}_{y} {E}_{x} \\ {E}_{y}^{2}\end{matrix} ) , \qquad ( 11 )$$

where the rotation matrices R and R′ are given by

$$R = ( \begin{matrix}cos φ & sin φ \\ - sin φ & cos φ\end{matrix} ) , {R}^{′} = ( \begin{matrix}{cos}^{2} φ & cos φsinφ & cos φsinφ & {sin}^{2} φ \\ - cos φsinφ & {cos}^{2} φ & - {sin}^{2} φ & cos φsinφ \\ - cos φsinφ & - {sin}^{2} φ & {cos}^{2} φ & cos φsinφ \\ {sin}^{2} φ & - cos φsinφ & - cos φsinφ & {cos}^{2} φ\end{matrix} ) . \qquad ( 12 )$$

In the presence of the C_{3z} symmetry in AB-AB TDBG, there is a symmetry constraint σ=R⁻¹σR′ with φ=2π/3 that leads to

$$σ = ( \begin{matrix}{σ}_{xxx} & - {σ}_{yyy} & - {σ}_{yyy} & - {σ}_{xxx} \\ - {σ}_{yyy} & - {σ}_{xxx} & - {σ}_{xxx} & {σ}_{yyy}\end{matrix} ) . \qquad ( 13 )$$

Thus, there are only two independent elements.

For an electric field of magnitude E that makes an angle ψ above the x-axis, the photocurrent density J exhibits a 2ψ dependence with respect to the optical field polarization:

$${J}_{x} = {E}^{2} ( {σ}_{xxx} cos 2 ψ - {σ}_{yyy} sin 2 ψ ) , \qquad ( 14 )$$

$${J}_{y} = {E}^{2} ( - {σ}_{xxx} sin 2 ψ - {σ}_{yyy} cos 2 ψ ) .$$

The polarization for the maximum or minimum photovoltage depends on the ratio between σₓₓₓ and σ_{yyy}. In other words, it changes with the top/bottom gate voltages in experiments. In our numerical calculations of σₓₓₓ and σ_{yyy}, the x and y axes are set to be the crystal coordinate axes, i.e., the original “zigzag” and “armchair” directions of the AB-bilayer graphene before twisting, respectively. In fact, the twisted AB-AB double bilayer graphene with angle θ in calculation is formed by rotating the top and bottom AB-bilayer graphene with angles −θ/2 and θ/2, respectively. σₓₓₓ and σ_{yyy} remain substantial (except for the case ΔV=0 which leads to σ_{yyy}=0) over a broad spectral range down to the terahertz regime and are highly tunable by electric fields. Increasing the inter-layer potential difference ΔV can lead to a larger bandgap at charge neutrality point (CNP), resulting in the vanishing σₓₓₓ and σ_{yyy} below a larger photon energy threshold when the system is charge neutral (E_{F}=0).

In principle, the measured photoresponse, i.e., J_{x′} in device coordinate system, can be written as J_{x′}=Jₓ cos φ+J_{y} sin φ and J_{y′}=−Jₓ sin φ+J_{y} cos φ, equivalent to a change of variable 2ψ→2ψ+φ in the current density equations above, in the case that the x′-axis (the photocurrent/photovoltage collection direction) makes an angle φ with the x-axis.

We now consider the symmetry group C₃ᵥ. With the (vertical) mirror symmetry [symbol] ₓ, any element that contains odd number of index x should vanish, resulting in

$$σ = ( \begin{matrix}0 & - {σ}_{yyy} & - {σ}_{yyy} & 0 \\ - {σ}_{yyy} & 0 & 0 & {σ}_{yyy}\end{matrix} ) . \qquad ( 15 )$$

In this case, there is only one independent non-zero element, and the photocurrent is given by

$${J}_{x} = - {E}^{2} {σ}_{yyy} sin 2 ψ , \qquad ( 16 )$$

$${J}_{y} = - {E}^{2} {σ}_{yyy} cos 2 ψ ,$$

also exhibiting a 2ψ dependence with respect to the optical field polarization. In contrast to the C_{3z} case, the polarization for the maximum or minimum photovoltage does not change with σ_{yyy} or the top/bottom gate voltages in experiments. Note that the analysis for the mirror symmetry [symbol] _{y} is similar. The C₃ᵥ symmetry is present in pristine graphene few-layers even with broken inversion symmetry, e.g., ABA-stack trilayer graphene (ABA-TLG) and AB-stack bilayer graphene (AB-BLG) under a D field. When inversion symmetry is broken in these non-moiré systems, an energy gap opens at K and K′ points, though nonzero, the BPVE is extremely small unless (i) the Fermi level is in the gap and (ii) the photon energy matches the gap. The band structure of ABA-TLG consists of gapped linear Dirac cones and gapped quadratic Dirac cones. One expects that its BPVE is negligible when the Fermi level is not in a sub-bandgap or the photon energy does not match the gap. This result on ABA-TLG has been demonstrated by our calculations. A comparison of the calculated nonlinear conductivity elements of ABA-TLG with that of TDBG at various E_{F} and at infrared wavelengths indicates that the magnitude of the conductivity elements in ABA-TLG (with σₓₓₓ=0) is significantly smaller than that in TDBG over a wide range of E_{F} for infrared photons. To conclude, in non-moiré pristine graphene few-layers with broken inversion symmetry, the phase of the Vₚₕ oscillations with respect to the polarization in linear BPVE cannot be tuned; meanwhile, the BPVE is appreciable only within a narrow spectral range with limited electrical tunability.

For AB-AB TDBG, in addition to the C_{3z} symmetry, there is a two-fold rotation symmetry about the x-axis: the C₂ₓ symmetry. The transformation under C₂ₓ effectively makes y→−y. As a result, any element in the conductivity tensor with odd number of index y should vanish, leaving only one independent non-zero element:

$$σ = ( \begin{matrix}{σ}_{xxx} & 0 & 0 & - {σ}_{xxx} \\ 0 & - {σ}_{xxx} & - {σ}_{xxx} & 0\end{matrix} ) . \qquad ( 17 )$$

Without any external bias to break the C₂ₓ symmetry, similar to the case under the C_{3y} symmetry discussed above, the polarization for the maximum or minimum photovoltage does not change with σₓₓₓ. However, the top/bottom gate voltages in experiment break the C₂ₓ symmetry. Note that the analysis for the C_{2y} symmetry is similar.

We now briefly comment on the C_{2z} symmetry, which is present in TBG but not in TDBG or other graphene moiré systems. The transformation under C_{2z} effectively makes (x,y)→(−x,−y). As a result, any element in the conductivity tensor with odd number of index x and y should vanish. Therefore, φ=0 when the C_{2z} symmetry is present, e.g., in TBG.

In experiments, TDBG was constructed from a Bernal bilayer graphene single crystal using the “tear-and-stack” approach (see Methods). It consists of the topmost and bottommost graphene monolayers and the twisted bilayer graphene (TBG) in between. As such, TDBG has a lower symmetry than TBG.

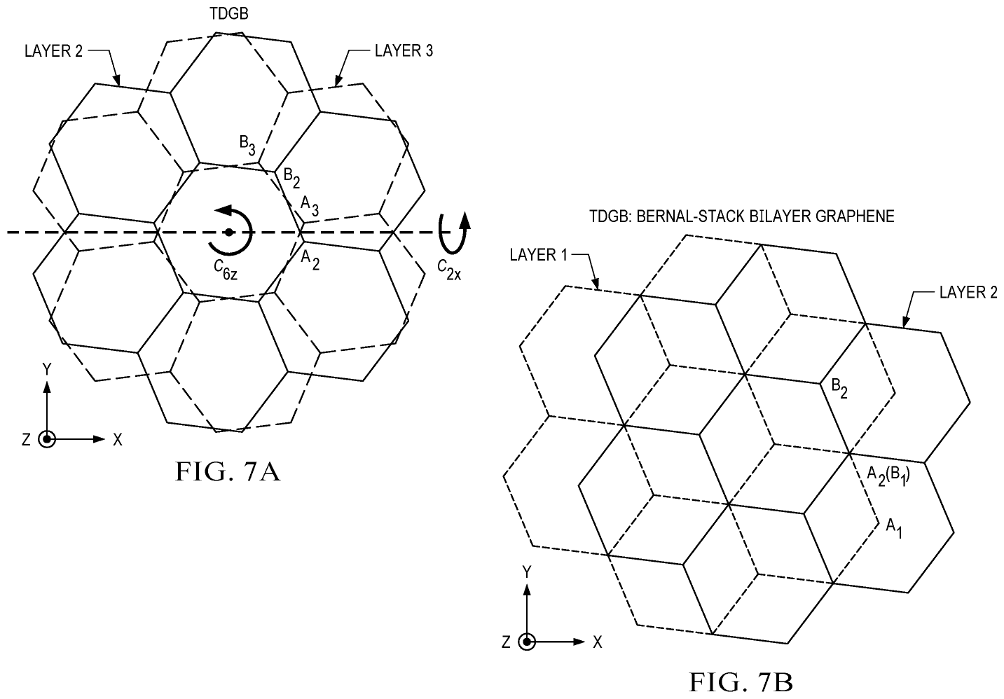

FIG. 7A depicts a schematic of the middle two layers of the lattice structure of TDBG, forming twisted bilayer graphene (TBG), and its C_{6z} and C₂ₓ axes. FIG. 7B depicts a schematic of the top or bottom Bernal bilayer graphene and how it changes under the C_{2z} rotation.

We first identify the symmetry of TBG. (i) As shown in FIG. 7A, TBG has a six-fold rotational axis normal to the x-y plane, inherited from graphene. This C_{6z} symmetry consists of the C_{2z} and C_{3z} symmetries. (ii) As illustrated in FIG. 7A, TBG also has a two-fold rotational axis along the x axis, i.e., a C₂ₓ symmetry, because this rotation interchanges the two layers and reverses the in-plane twist angle simultaneously. (iii) Under a horizontal mirror reflection, while their relative in-plane twist angle does not change, the relative top-bottom position of the two layers is reversed, amounting to flipping the twist angle. Twisting also makes the vertical mirror planes of the two layers no longer coincident. Thus, TBG has no mirror symmetry. (iv) Because the inversion is the product of the C_{2z} rotation and the horizontal mirror reflection, (i) and (iii) indicates that the inversion symmetry is broken in TBG.

This analysis suggests that the possible symmetries of TDBG are the C_{3z}, C_{2z}, and C₂ₓ symmetries. Now, we show that the two two-fold rotational symmetries are broken in our TDBG devices. (i) As shown in FIG. 7B, the C_{2z} rotation interchanges the A and B sublattices of each layer, thereby changing AB stacking to BA stacking (or vice versa) for each Bernal bilayer. Clearly, the C_{2z} symmetry is broken in Bernal bilayer, not to mention in TDBG. (ii) The C₂ₓ symmetry is intact in TDBG. However, since the C₂ₓ symmetry requires the top and bottom layers to have, e.g., the same potential energy and the same dielectric environment, it can be easily broken by a perpendicular D field or any asymmetry between the top and bottom hBN layers.

Therefore, the TDBG only has the C_{3z} and C₂ₓ symmetries, and the latter is broken under a perpendicular D field or with asymmetric hBN encapsulation. We stress that in our work, TDBG cannot be replaced by the simpler TBG or pristine graphene multilayers. For TBG, its extra C_{2z} symmetry dictates σ_{yyy}=σₓₓₓ=0 and hence no photoresponse. For graphene multilayers including both Bernal and rhombohedral stacking orders, their extra vertical mirror symmetry requires that σₓₓₓ=0, and hence the phase of the photocurrent (related to the ratio σₓₓₓ/σ_{yyy}) cannot be tuned, even in the presence of a perpendicular D field or an hBN asymmetry.

As used herein, the phrase “a number” means one or more. The phrase “at least one of”, when used with a list of items, means different combinations of one or more of the listed items may be used, and only one of each item in the list may be needed. In other words, “at least one of” means any combination of items and number of items may be used from the list, but not all of the items in the list are required. The item may be a particular object, a thing, or a category.

The description of the different illustrative embodiments has been presented for purposes of illustration and description, and is not intended to be exhaustive or limited to the embodiments in the form disclosed. Many modifications and variations will be apparent to those of ordinary skill in the art. Further, different illustrative embodiments may provide different features as compared to other desirable embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

The illustrative embodiments provide:

A photodetector comprising:
a twisted Moiré superlattice;
a first dielectric layer disposed on a first side of the Moiré superlattice;
a second dielectric layer disposed on a second side of the Moiré superlattice;
two contact electrodes connected to the Moiré superlattice, wherein the contact electrodes collect photovoltages or photocurrents in response to incident light that excites the Moiré superlattice; and
one or more tuning controls that tune the photovoltages or photocurrents collected by the contact electrodes and produce photovoltage maps or photocurrent maps based on the photovoltages or photocurrents.

The photodetector further comprising a neural network in communication with the photodetector, wherein the neural network is trained to concurrently determine intensity, polarization, and wavelength of the incident light according to a photovoltage map or photocurrent map generated in response to the incident light by the tuning controls.

The photodetector, wherein twisted Moiré superlattice comprises at least one of:
a graphene monolayer or few-layers;
transition-metal dichalcogenide monolayer or few-layers;
black phosphorus few-layers or thin film;
patterned silicon thin film;
patterned germanium thin film;
patterned silicon germanium thin film;
patterned group II-group VI thin film; or
patterned group III-group V thin film.

The photodetector, wherein the first and second dielectric layers comprise hexagonal boron nitride.

The photodetector, wherein the contact electrodes are made of gold and chromium.

The photodetector, wherein the tuning controls comprise:
a top gate electrode disposed on a side of the first dielectric layer distal to the Moiré superlattice; and
a bottom gate electrode disposed on a side of the second dielectric layer distal to the Moiré superlattice.

The photodetector, wherein the top gate electrode is made of graphene or metal.

The photodetector, wherein the bottom gate electrode is made of silicon.

The photodetector, wherein the neural network comprises a convoluted neural network.

The photodetector, wherein the tuning controls are tuning gates.

The photodetector, wherein the tuning parameters for the photovoltage maps or photocurrent maps comprise at least one of voltage, current, temperature, strain, or magnetic field.

A method for training a neural network to measure quantities of light, the method comprising:
inputting a set of known data points regarding light intensity, polarization, and wavelength and corresponding photovoltage maps or photocurrent maps into a neural network as a training dataset;
shining a set of incident light of the known intensity, polarization, and wavelength on a photodetector comprising a twisted Moiré superlattice, wherein the photodetector is in communication with the neural network;
generating a set of photovoltage maps or photocurrent maps as functions of voltages generated by one or more tuning gates in the photodetector that tune photovoltages or photocurrents collected by contact electrodes connected to the Moiré superlattice in response to excitement of the Moiré superlattice by the incident light;
inputting the photovoltage maps or photocurrent maps into the neural network;
concurrently predicting, by the neural network, the intensity, polarization, and wavelength of the incident light from each of the photovoltage maps or photocurrent maps;
comparing the predicted intensity, polarization, and wavelength to the known intensity, polarization, and wavelength in the set of known data points;
in response to predicted intensity, polarization, and wavelength that do not match the known intensity, polarization, and wavelength, adjusting parameters of the neural network; and
retraining the neural network until errors of all training data reach are minimized.

The training method, wherein the neural network is a convolutional neural network.

A method for measuring qualities of light, the method comprising:
shining an incident light of unknown intensity, polarization, and wavelength on a photodetector, the photodetector comprising:
a twisted Moiré superlattice;
a first dielectric layer disposed on a first side of the Moiré superlattice;
a second dielectric layer disposed on a second side of the Moiré superlattice;
two contact electrodes connected to the Moiré superlattice, wherein the contact electrodes collect photovoltages or photocurrents in response to excitement of the Moiré superlattice by the incident light; and
one or more tuning gates that tune the photovoltages or photocurrents collected by the contact electrodes;
generating a photovoltage map or photocurrent map as a function of voltages generated by the tuning gates in response to excitement of the Moiré superlattice by the incident light;
inputting the photovoltage map or photocurrent map into a neural network in communication with the photodetector; and
concurrently determining, by the neural network, the intensity, polarization, and wavelength of the incident light according to the photovoltage map or photocurrent map.

The method, wherein twisted Moiré superlattice comprises at least one of:
a graphene monolayer or few-layers;
transition-metal dichalcogenide monolayer or few-layers;
black phosphorus few-layers or thin film;
patterned silicon thin film;
patterned germanium thin film;
patterned silicon germanium thin film;
patterned group II-group VI thin film; or
patterned group III-group V thin film.

The method, wherein the first and second dielectric layers comprise hexagonal boron nitride.

The method, wherein the contact electrodes are made of gold and chromium.

The method, wherein the tuning gates comprise:
a top gate electrode disposed on a side of the first dielectric layer distal to the Moiré superlattice; and
a bottom gate electrode disposed on a side of the second dielectric layer distal to the Moiré superlattice.

The method, wherein the top gate electrode is made of graphene or metal.

The method, wherein the bottom gate electrode is made of silicon.

The method, wherein the neural network comprises a convoluted neural network.

1. A photodetector comprising:
a twisted Moiré superlattice;
a first dielectric layer disposed on a first side of the Moiré superlattice;
a second dielectric layer disposed on a second side of the Moiré superlattice;
two contact electrodes connected to the Moiré superlattice, wherein the contact electrodes collect photovoltages or photocurrents in response to incident light that excites the Moiré superlattice; and
one or more tuning controls that tune the photovoltages or photocurrents collected by the contact electrodes and produce photovoltage maps or photocurrent maps based on the photovoltages or photocurrents.

2. The photodetector of claim 1, further comprising a neural network in communication with the photodetector, wherein the neural network is trained to concurrently determine intensity, polarization, and wavelength of the incident light according to a photovoltage map or photocurrent map generated in response to the incident light by the tuning controls.

3. The photodetector of claim 1, wherein the twisted Moiré superlattice comprises at least one of:
a graphene monolayer or few-layers;
transition-metal dichalcogenide monolayer or few-layers;
black phosphorus few-layers or thin film;
patterned silicon thin film;
patterned germanium thin film;
patterned silicon germanium thin film;
patterned group II-group VI thin film; or
patterned group III-group V thin film.

4. The photodetector of claim 1, wherein the first and second dielectric layers comprise hexagonal boron nitride.

5. The photodetector of claim 1, wherein the contact electrodes are made of gold and chromium.

6. The photodetector of claim 1, wherein the tuning controls comprise:
a top gate electrode disposed on a side of the first dielectric layer distal to the Moiré superlattice; and
a bottom gate electrode disposed on a side of the second dielectric layer distal to the Moiré superlattice.

7. The photodetector of claim 6, wherein the top gate electrode is made of graphene or metal.

8. The photodetector of claim 6, wherein the bottom gate electrode is made of silicon.

9. The photodetector of claim 1, wherein the neural network comprises a convoluted neural network.

10. The photodetector of claim 1, wherein the tuning controls comprise tuning gates.

11. The photodetector of claim 1, wherein tuning parameters for the photovoltage maps or photocurrent maps comprise at least one of:
voltage;
current;
temperature;
strain; or
magnetic field.

12. A method for training a neural network to measure quantities of light, the method comprising:
inputting a set of known data points regarding light intensity, polarization, and wavelength and corresponding photovoltage maps or photocurrent maps into a neural network as a training dataset;
shining a set of incident light of the known intensity, polarization, and wavelength on a photodetector comprising a twisted Moiré superlattice, wherein the photodetector is in communication with the neural network;
generating a set of photovoltage maps or photocurrent maps as functions of voltages generated by one or more tuning gates in the photodetector that tune photovoltages or photocurrents collected by contact electrodes connected to the Moiré superlattice in response to excitement of the Moiré superlattice by the incident light;
inputting the photovoltage maps or photocurrent maps into the neural network;
concurrently predicting, by the neural network, the intensity, polarization, and wavelength of the incident light from each of the photovoltage maps or photocurrent maps;
comparing the predicted intensity, polarization, and wavelength to the known intensity, polarization, and wavelength in the set of known data points;
in response to predicted intensity, polarization, and wavelength that do not match the known intensity, polarization, and wavelength, adjusting parameters of the neural network; and
retraining the neural network until errors of all training data reach a predefined minimum.

13. The method of claim 12, wherein the neural network is a convolutional neural network.

14. A method for measuring qualities of light, the method comprising:
shining an incident light of unknown intensity, polarization, and wavelength on a photodetector, the photodetector comprising:
a twisted Moiré superlattice;
a first dielectric layer disposed on a first side of the Moiré superlattice;
a second dielectric layer disposed on a second side of the Moiré superlattice;
two contact electrodes connected to the Moiré superlattice, wherein the contact electrodes collect photovoltages or photocurrents in response to excitement of the Moiré superlattice by the incident light; and
one or more tuning gates that tune the photovoltages or photocurrents collected by the contact electrodes;
generating a photovoltage map or photocurrent map as a function of voltages generated by the tuning gates in response to excitement of the Moiré superlattice by the incident light;
inputting the photovoltage map or photocurrent map into a neural network in communication with the photodetector; and
concurrently determining, by the neural network, the intensity, polarization, and wavelength of the incident light according to the photovoltage map or photocurrent map.

15. The method of claim 14, wherein twisted Moiré superlattice comprises at least one of:
a graphene monolayer or few-layers;
transition-metal dichalcogenide monolayer or few-layers;
black phosphorus few-layers or thin film;
patterned silicon thin film;
patterned germanium thin film;
patterned silicon germanium thin film;
patterned group II-group VI thin film; or
patterned group III-group V thin film.

16. The method of claim 14, wherein the first and second dielectric layers comprise hexagonal boron nitride.

17. The method of claim 14, wherein the contact electrodes are made of gold and chromium.

18. The method of claim 14, wherein the tuning gates comprise:
a top gate electrode disposed on a side of the first dielectric layer distal to the Moiré superlattice; and
a bottom gate electrode disposed on a side of the second dielectric layer distal to the Moiré superlattice.

19. The method of claim 18, wherein the top gate electrode is made of graphene or metal.

20. The method of claim 18, wherein the bottom gate electrode is made of silicon.

21. The method of claim 14, wherein the neural network comprises a convoluted neural network.
